(19) United States
(12) Patent Application Publication
(10) Pub. No.: US 2012/0292090 A1
(43) Pub. Date: Nov. 22, 2012

(54) PRINTED CIRCUIT BOARD

(75) Inventors: TSUNG-SHENG HUANG, Tu-Cheng (TW); CHUN-JEN CHEN, Tu-Cheng (TW); DUEN-YI HO, Tu-Cheng (TW); WEI-CHIEH CHOU, Tu-Cheng (TW)

(73) Assignee: HON HAI PRECISION INDUSTRY CO., LTD., Tu-Cheng (TW)

(21) Appl. No.: 13/166,790

(22) Filed: Jun. 22, 2011

(30) Foreign Application Priority Data
May 20, 2011 (TW) 100117723

(51) Int. Cl. H05K 1/11

(52) U.S. Cl. 174/261

(57) ABSTRACT

A printed circuit board (PCB) comprising a first circuit area, a second circuit area, a plurality of connecting elements, and a plurality of connecting terminals placed on the first circuit area, wherein the first circuit area are electrically connected to the second circuit area through the plurality of connecting elements, the plurality of connecting elements are arranged in sequence to extend toward the plurality of connecting terminals, to form shortest current paths from the second circuit area via corresponding one of the connecting elements to the connecting terminals, respectively, and each shortest current path between the corresponding one of the connecting elements and the corresponding one of the connecting terminals is uncoated with conductive material.

### BACKGROUND

1. Technical Field

The present disclosure relates to a printed circuit board (PCB).

2. Description of Related Art

Referring to FIG. 3, a conventional PCB 1 includes a first circuit area 11, a second circuit area 12, and a number of connecting terminals 13, 14 and 15. The connecting terminals 13-15 are arranged on the first circuit area 11, and each connecting terminal is electrically connected to a load. The first circuit area 11 and the second circuit area 12 have different operating currents, but the operating voltage of them may be identical, such as 12 volts. The current of the second circuit area 12 flows to the first circuit area 11 through connecting elements 16-19, and further flows to the connecting terminal 14 through a current path 141, flows to the connecting element 15 through a current path 151, and also flows to the connecting element 13 through a current path 131. Since the loads need high current, the first circuit area 11 is generally connected to the second circuit area 12 through the connecting elements 16-19. However, the currents passing through the connecting elements 16-19 are not the same, in one case, for instance, the current passing through connecting element 16 is about 14.982 amps, through 17 is about 13.465 amps, through 18 is about 11.276 amps, and through 19 is about 12.479 amps. The difference between the largest and smallest currents is 3.706 amps, which is great deal of current. This will result in high temperatures at some locations on the PCB 1, which may make the circuit unstable or even damage it.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of a first exemplary embodiment of a printed circuit board.

FIG. 2 is a schematic diagram of a second exemplary embodiment of a printed circuit board.

FIG. 3 is a schematic diagram of a conventional printed circuit board.

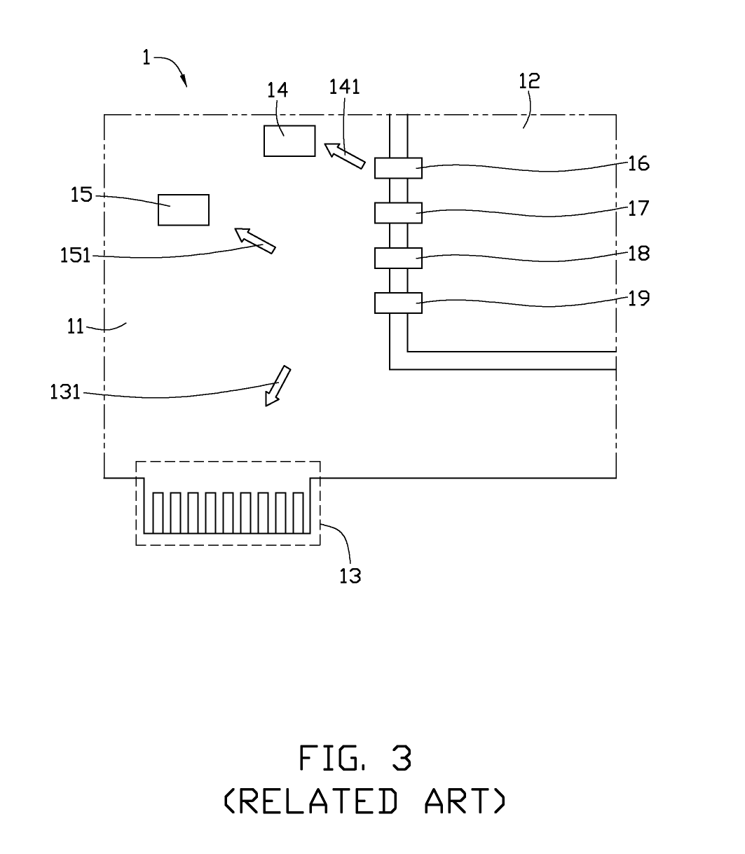

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

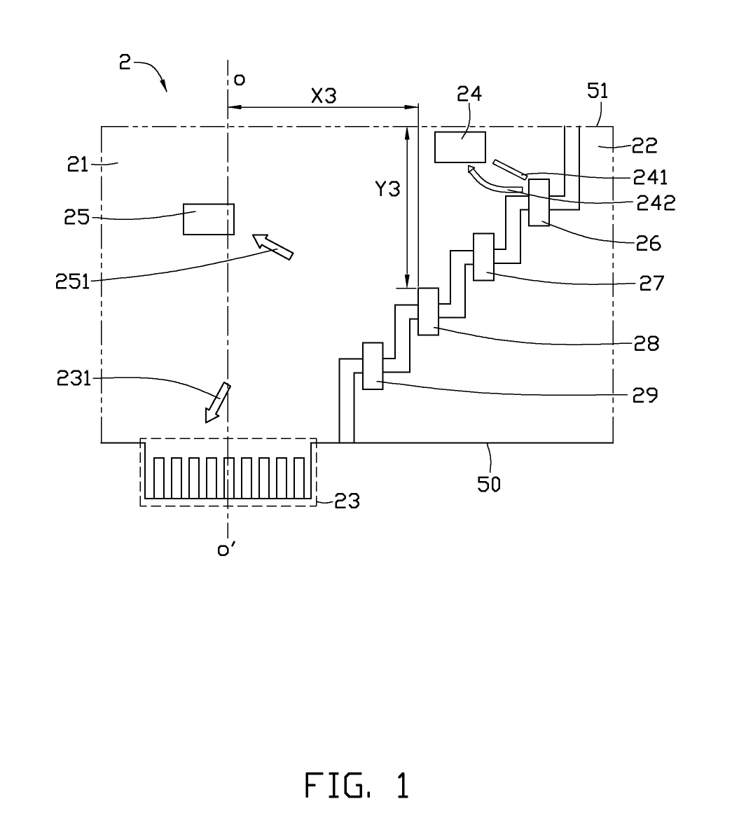

Referring to FIG. 1, a first exemplary embodiment of a printed circuit board (PCB) 2 includes a first circuit area 21, a second circuit area 22, a plurality of connecting elements 26-29, and a plurality of connecting terminals 23-25. The number of the connecting elements is a matter of design, and this can be two or more according to the demands of any practical application.

The connecting terminal 23 is arranged on a first side 50 of the PCB 2, for being electrically connected to a first load (not shown). The connecting terminal 24 is arranged on the first circuit area 21 and adjacent to a second side 51 of the PCB 2 opposite to the first side 50, and also adjacent to the second circuit area 22, to be electrically connected to a second load (not shown). The connecting terminal 25 is arranged on the first circuit area 21 and located between the connecting terminals 23 and 24, and away from the second circuit area 22, to be electrically connected to a third load (not shown). The PCB 2 can deliver current into the loads connected to the connecting terminals 23-25, so the connecting terminals 23-25 can be considered as load ports. The connecting terminal 23 can be an edge connector in accordance with peripheral component interconnection (PCI), or other standard. The connecting terminals 24 and 25 may be any type of connector.

The current of the first circuit area 21 is less than the current of the second circuit area 22. The first circuit area 21 is electrically connected to the second circuit area 22 through the connecting elements 26-29. That is, the current in the second circuit area 22 passes through the connecting elements 26-29 to flow to the first circuit area 21, and further flows to the connecting terminal 24 through a current path 241, flows to the connecting terminal 25 through a current path 251, and also flows to the connecting terminal 23 through a current path 231. In one embodiment, the connecting elements 26-29 are disposed on the PCB 2 and arranged in sequence to extend toward the connecting terminals 23-25, to create the shortest current path from the circuit area 22 to the connecting terminals 23-25.

The connecting elements 26-29 may be resistors, metal-oxide-semiconductor field-effect transistors (MOSFETs), or other resistive components. In the connection area between the first circuit area 21 and the second circuit area 22, the connecting elements 26-29 are arranged in such a manner, for example, that the connecting terminal 23 has the center line OO′ perpendicular to the first and the second sides 50 and 51 of the printed circuit board 2, and the straight-line distances between the connecting elements 26-29 and the center line OO′ are respectively X1, X2, X3, and X4 (in FIG. 1, only the distance X3 is shown). Straight-line distances between the connecting elements 26-29 and the second side 51 are respectively Y1, Y2, Y3, and Y4 (in FIG. 1, only the distance Y3 is shown). Thus, the shorter the distance Xi, the proportionately larger Yi the becomes. The closer the connecting elements 26-29 can be to the center line OO′, the longer the straight-line distance Yi can be. In one embodiment, the connecting elements 26-29 are arranged in a stair-like manner

The connecting elements 26-29 are arranged in a stair-like manner to shorten the distances between the connecting elements 27-29 and the connecting terminals 23 and 25 and thus the current paths 251 and 231. Therefore, the connecting element 26 can be restricted to the level of current it actually requires and the remaining current can take a bypass route to the connecting elements 27-29 which are further away from the connecting terminal 24. Instead of allowing maximum current at this point, this will reduces the current passing through the connecting element 26 and avoid high temperatures developing at the connecting elements 26.

In addition, the a longitudinal portion of conductive materials, such as the copper coating or cladding on the current path 241 can be removed, to increase the resistance between the connecting element 26 and the connecting terminal 24. Thus, the shortest current path 241 can effectively become a longer current path 242, which will further reduce the current passed through the connecting element 26.

Current at the connecting elements 26-29 is obtained as in table 1:

TABLE 1

Connecting elements

| | 26 | 27 | 28 | 29 |
|---|---|---|---|---|
| current (A) | 12.213 | 13.173 | 11.759 | 13.906 |

As a result, the current passing through the connecting elements 26 is reduced, and the difference between the largest and smallest currents is 2.147 amperes. Thus, a very large current and potential high temperatures at one of the connecting elements 26-29 can be avoided, and the reliability and lifespan of the PCB 2 improves.

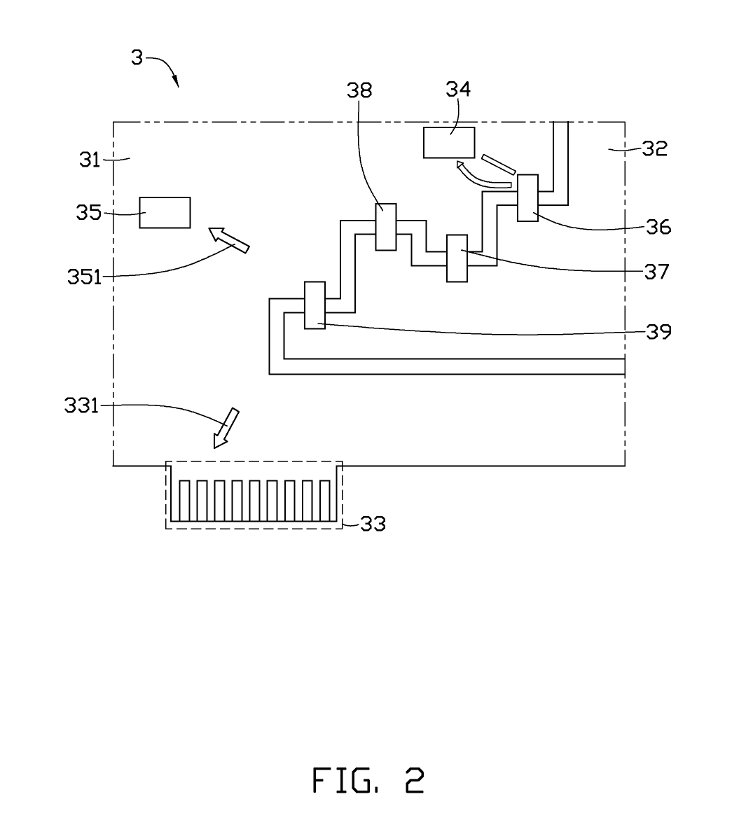

Referring to FIG. 2, a printed circuit board (PCB) 3 in accordance with a second embodiment is provided. The PCB 3 is similar to the PCB 2 of the first embodiment, except for the arrangement of the connecting elements 36-39. The connecting elements 36-39 in the second embodiment are arranged in a zigzag shape. The distances between the connecting elements 37-39 and corresponding connecting terminals 33 and 35 are shortened, to thus shorten current paths 351 and 331. Thus, current from a second circuit area 32 can be conducted to the connecting elements 37-39 which are more distant from the connecting terminal 34, thereby reducing the current passing through the connecting element 36 and avoiding high temperatures at the connecting elements 36.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board (PCB) comprising a first circuit area, a second circuit area, a plurality of connecting elements, and a plurality of connecting terminals placed on the first circuit area, wherein the first circuit area are electrically connected to the second circuit area through the plurality of connecting elements, the plurality of connecting elements are arranged in sequence to extend toward the plurality of connecting terminals, to form shortest current paths from the second circuit area via corresponding one of the connecting elements to the connecting terminals, respectively, and each shortest current path between the corresponding one of the connecting elements and the corresponding one of the connecting terminals is uncoated with conductive material.

2. The PCB of claim 1, wherein the connecting elements are arranged in stair-like manner.

3. The PCB of claim 1, wherein the connecting elements are arranged in zigzag shape.

4. The PCB of claim 1, wherein one of the connecting terminals is an edge connector meeting peripheral component interconnection (PCI) standard, and the other connecting terminals are connectors.

5. The PCB of claim 1, wherein the current of the second circuit area is greater than the current of the first circuit area.
